(19) United States
(12) Patent Application Publication
(10) Pub. No.: US 2012/0268905 A1
(43) Pub. Date: Oct. 25, 2012

(54) SUBSTRATE AND MOBILE TERMINAL DEVICE

(75) Inventor: Ken'ichirou Watase, Kanagawa (JP)

(73) Assignee: Panasonic Corporation, Osaka (JP)

(21) Appl. No.: 13/511,106

(22) PCT Filed: Nov. 26, 2010
(86) PCT No.: PCT/JP2010/006909

§ 371 Date: May 21, 2012

(30) Foreign Application Priority Data
Nov. 27, 2009 (JP) 2009-270035

(51) Int. Cl. H05K 7/02

(52) U.S. Cl. 361/752

(57) ABSTRACT

Provided is a substrate, wherein wire-breaking of a plurality of signal lines can be detected, circuit configuration can be simplified, and processing load accompanying wire-breaking detection processing can be minimized. This substrate is a multi-layer structured FPC substrate (203), having a plurality of layers (L1-L4) insulated from each other. In this FPC substrate (203), a signal line (302) is provided on each of the plurality of layers (L1-L4). A dummy line (303) is provided, by being bent from one layer among the plurality of layers (L1-L4) towards a layer other than the one of the layers, on both the one of the layers and the layer other than the one of the layers.

### TECHNICAL FIELD

The present invention particularly relates to a substrate and a mobile terminal device for detecting wire-breaking of a signal line.

### BACKGROUND ART

In recent years, there has been mainly used a folding mobile terminal device in which multiple casings are openably connected via hinges. In such a mobile terminal device, in many cases, each function block and a control circuit are arranged over multiple casings for an optimum arrangement of each function block in the casings and integration of the control circuit for operating each function block. Therefore, various signals need to be sent between the casings and there are provided signal lines and power supply lines for connecting circuit substrates arranged in the respective casings. In the mobile terminal device having an open/close mechanism with which the signal lines are provided, there is a problem that the signal lines or power supply lines are easily broken at a portion movable along with the open/close. Therefore, it is important to detect and report that the signal lines or power supply lines can be broken in order to prevent an abrupt failure or abrupt poor operation.

There is conventionally known a device for detecting and reporting that a signal line can be broken (Patent Literature 1, for example). Patent Literature 1 discloses that release of a flexible print (described as “FPC” below) substrate or wire-breaking of an internal wiring is detected and its result is reported to a liquid crystal device. Specifically, two detection lines for detecting release or wire-breaking are formed separately from a control signal line in the FPC substrate arranged between a liquid crystal panel and a liquid crystal driver substrate. In Patent Literature 1, the voltage values of the two detection lines are subjected to OR, respectively, to detect wire-breaking and to display alarm information on the liquid crystal panel. In this way, Patent Literature 1 is to detect and report wire-breaking of the control signal line for connecting the liquid crystal panel as a display function block and the liquid crystal driver.

### CITATION LIST

### Patent Literature

PL1
Japanese Patent Application Laid-Open No. 2008-15287

### SUMMARY OF INVENTION

### Technical Problem

However, Patent Literature 1 is directed for detecting wire-breaking of a signal line in one function block, and as many wire-breaking detection circuits shown in Patent Literature 1 as function blocks need to be provided for detecting wire-breaking of each signal line in multiple function blocks. Thus, in Patent Literature 1, there is a problem that a wire-breaking detection circuit is complicated and a processing load on the wire-breaking detection processing increases.

It is an object of the present invention to provide a substrate and a mobile terminal device capable of detecting wire-breaking of multiple signal lines, simplifying a circuit structure and restricting a processing load on the wire-breaking detection processing.

### Solution to Problem

A substrate according to the present invention is a multilayer structured substrate having multiple mutually-insulated layers, and comprises signal lines provided in the respective layers, and dummy lines bent from one layer among the layers toward a layer other than the one layer and provided in both the one of the layers and the layer other than the one of the layers.

A mobile terminal device according to the present invention comprises a first casing, a second casing, a multilayer structured substrate that connects the first casing and the second casing and has multiple mutually-insulated layers, signal lines provided in the respective layers, dummy lines that travel between the first casing and the second casing and are bent from one layer among the layers toward a layer other than the one layer to be provided in both the one of the layers and the layer other than the one of the layers, a wire-breaking detection section that detects wire-breaking of the dummy line, and an alarm section that, when the wire-breaking detection section detects wire-breaking of the dummy line, gives an alarm about the wire-breaking of a signal line of the one layer or the layer other than the one layer.

### Advantageous Effects of Invention

According to the present invention, it is possible to detect wire-breaking of multiple signal lines and to simplify a circuit structure, thereby restricting a processing load on a wire-breaking detection processing.

### BRIEF DESCRIPTION OF DRAWINGS

FIG. 1 is a perspective view of an open state of a mobile terminal device according to Embodiment 1 of the present invention;

FIG. 2 is a plan view of an open state of the mobile terminal device according to Embodiment 1 of the present invention;

FIG. 3 is a plan view of essential sections of the mobile terminal device according to Embodiment 1 of the present invention;

FIG. 4 is side vide of a FPC substrate according to Embodiment 1 of the present invention;

FIG. 5 is a plan view of essential sections of a mobile terminal device according to Embodiment 2 of the present invention; and

FIG. 6 is a plan view of essential sections of a mobile terminal device according to Embodiment 3 of the present invention.

### DESCRIPTION OF EMBODIMENTS

Embodiments of the present invention will be described below in detail with reference to the drawings.

### Embodiment 1

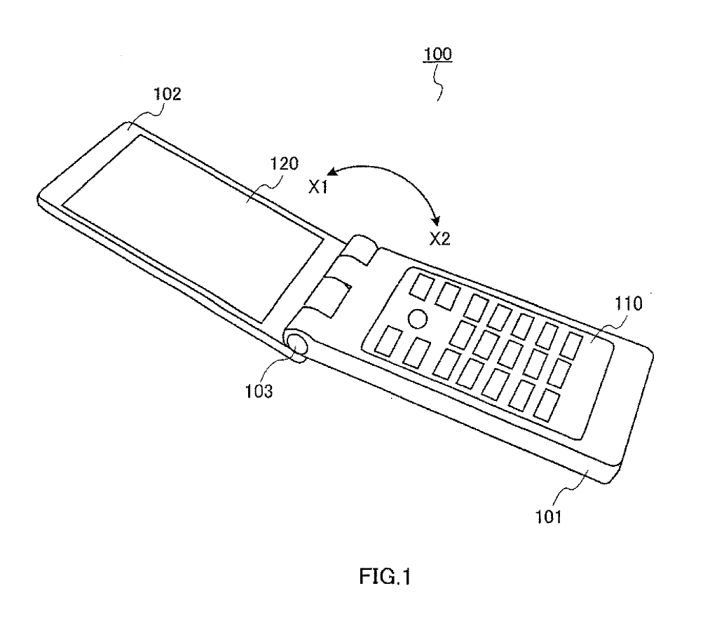

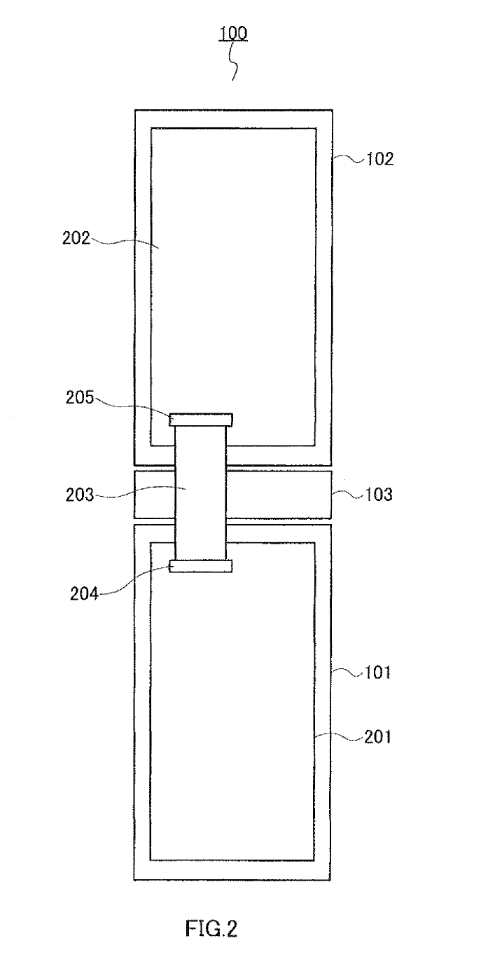

FIG. 1 is a perspective view of an open state of mobile terminal device 100 according to Embodiment 1 of the present invention. FIG. 2 is a plan view of an open state of mobile terminal device 100.

As shown in FIG. 1, mobile terminal device 100 comprises first casing 101, second casing 102 and hinge section 103.

First casing 101 has operation section 110, first circuit substrate 201, and connector 204. Second casing 102 has display section 120, second circuit substrate 202, and connector 205. Each constituent will be described below in detail.

First casing 101 is substantially box-shaped, and is connected with second casing 102 rotatably in X1 or X2 (see FIG. 1) direction via hinge section 103. First casing 101 has first circuit substrate 201 therein. First casing 101 has operation section 110 that is operated by a user and enables e-mails to be transmitted and received, or digital television broadcast to be viewed.

Second casing 102 is substantially box-shaped, and is connected with first casing 101 rotatably in X1 or X2 direction via hinge section 103. Second casing 102 has second circuit substrate 202 therein. Second casing 102 has display section 120 that displays characters and the like input by operation section 110 or images and the like of digital television broadcast received by mobile terminal device 100.

Hinge section 103 rotatably connects first casing 101 and second casing 102 in X1 or X2 direction. Hinge section 103 has FPC substrate 203 therein.

First circuit substrate 201 has connector 204 connected with FPC substrate 203. First circuit substrate 201 is electrically connected with second circuit substrate 202 via connector 204, FPC substrate 203 and connector 205. The circuit structure of first circuit substrate 201 will be described later.

Second circuit substrate 202 has connector 205 connected with FPC substrate 203. Second circuit substrate 202 is electrically connected with first circuit substrate 201 via connector 205, FPC substrate 203 and connector 204. First circuit substrate 201, second circuit substrate 202 and FPC substrate 203 may not be separately formed, first circuit substrate 201 and FPC substrate 203 may be integrally formed, and second circuit substrate 202 and FPC substrate 203 may be separately formed. First circuit substrate 201 and FPC substrate 203 may be separately formed and second circuit substrate 202 and FPC substrate 203 may be integrally formed. When first circuit substrate 201 and FPC substrate 203 are integrally formed, connector 204 may not he required. When second circuit substrate 202 and FPC substrate 203 are integrally formed, connector 205 may not be required.

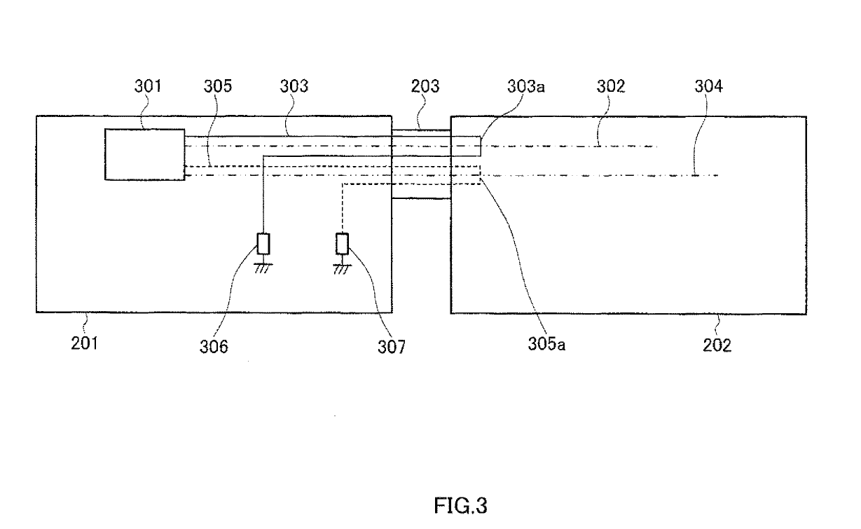

A structure of essential sections of mobile terminal device 100 will be described below in detail with reference to FIG. 3. FIG. 3 is a plan view of essential sections of mobile terminal device 100. In FIG. 3, like reference numerals are denoted to the same constituents as those of FIGS. 1 and 2, and an explanation thereof will be omitted. In FIG. 3, an explanation of first casing 101, second casing 102 and hinge section 103 will be omitted for convenience of description.

First circuit substrate 201 has circuit section 301. First circuit substrate 201 prints and forms first signal line 302 and first dummy line 303 therein. First circuit substrate 201 prints and forms second signal line 304 and second dummy line 305 therein. First circuit substrate 201 has resistor 306 and resistor 307.

Second circuit substrate 202 prints and forms first signal line 302 and second signal line 304 therein. Second circuit substrate 202 prints and forms first dummy line 303 and second dummy line 305 therein. Second circuit substrate 202 has a plurality of different function blocks (not shown). First signal line 302, first dummy line 303, second signal line 304 and second dummy line 305 may not be printed and formed, and may be separately formed from second circuit substrate 202 and may be formed in any method. The function block is configured of a camera, IrDA, or an electronic component necessary for operating LCD.

FPC substrate 203 is made of a flexible material. FPC substrate 203 forms first signal line 302, first dummy line 303, second signal line 304, and second dummy line 305 therein. FPC substrate 203 is provided with insulation sections that insulate first signal line 302, first dummy line 303, second signal line 304 and second dummy line 305 mutually and from outside.

Circuit section 301 is electrically connected to first signal line 302, first dummy line 303, second signal line 304 and second dummy line 305. Circuit section 301 supplies power to the function blocks, which are the connection destinations of first signal line 302 and second signal line 304. Circuit section 301 outputs a control signal to first signal line 302 and second signal line 304 for controlling the operations of the function blocks, which are the connection destinations of first signal line 302 and second signal line 304. Circuit section 301 has a constant current source that supplies a constant current to first dummy line 303 and second dummy line 305. Circuit section 301 detects wire-breaking of first dummy tine 303 and second dummy line 305. A wire-breaking detection method will be described later.

First signal line 302 connects circuit section 301 with the function block (not shown) provided in second casing 102. First signal line 302 is printed and formed in first circuit substrate 201, is formed in FPC substrate 203 by hinge section 103, and is printed and formed in second circuit substrate 202. First signal line 302 is formed as a continuous signal line over first circuit substrate 201, FPC substrate 203 and second circuit substrate 202.

First dummy line 303 is electrically connected at one end to circuit section 301. First dummy line 303 is extended from one end connected with circuit section 301 toward second casing 102, travels between first circuit substrate 201 and second circuit substrate 202, and is earthed at the other end on a ground section of first circuit substrate 201 via resistor 306. First dummy line 303 is provided at the horizontally outer sides of first signal line 302. The horizontally outer sides of first signal line 302 mean the upper side and the lower side of first signal line 302 in FIG. 3. First dummy line 303 has folding section 303a in second circuit substrate 202. First dummy line 303 is formed as a continuous dummy line over first circuit substrate 201, FPC substrate 203 and second circuit substrate 202.

Second signal line 304 connects circuit section 301 with the function block (not shown) provided in second casing 102. First signal line 302 is printed and formed in first circuit substrate 201, is formed in FPC substrate 203 by hinge section 103, and is printed and formed in second circuit substrate 202. Second signal line 304 is formed as a continuous signal line over first circuit substrate 201, FPC substrate 203 and second circuit substrate 202.

Second dummy line 305 is electrically connected at one end to circuit section 301. Second dummy line 305 is extended from one end connected with circuit section 301 toward second casing 102, travels between first circuit substrate 201 and second circuit substrate 202, and is earthed at the other end on the ground section of first circuit substrate 201 via resistor 307. Second dummy line 305 is provided at the horizontally outer sides of second signal line 304. The horizontally outer sides of second signal line 304 mean the upper side and the lower side of second signal line 304 in FIG. 3. Second dummy line 305 has folding section 305a in second circuit substrate 202. Second dummy line 305 is formed as a continuous dummy line over first circuit substrate 201, FPC substrate 203 and second circuit substrate 202.

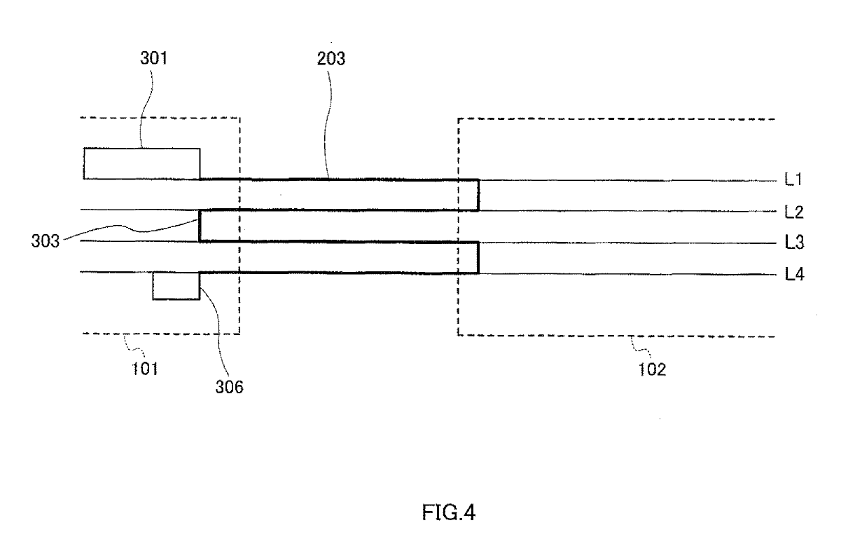

A structure of FPC substrate 203 will be described below with reference to FIG. 4. FIG. 4 is a side view of FPC substrate 203.

FPC substrate 203 is multilayer structured as shown in FIG. 4. Specifically, FPC substrate 203 has a four-layer structure of first layer L1, second layer L2, third layer L3 and fourth layer L4. The insulation sections (not shown) mutually isolate first layer L1 and second layer L2, second layer L2 and third layer L3, and third layer L3 and fourth layer L4. First dummy line 303 is extended from first circuit substrate 201 toward second circuit substrate 202 in first layer L1. Since first dummy line 303 is bent downward in the middle of first layer L1, is bent toward first circuit substrate 201 in second layer L2, so that first dummy line 303 is extended from second circuit substrate 202 toward first circuit substrate 201 in second layer L2. Since first dummy line 303 is bent downward in the middle of second layer L2, is bent toward second circuit substrate 202 in third layer L3, so that first dummy line 303 is extended from first circuit substrate 201 toward second circuit substrate 202 in third layer L3. Since first dummy line 303 is bent downward in the middle of third layer L3, is bent toward first circuit substrate 201 in fourth layer L4, so that first dummy line 303 is extended from second circuit substrate 202 toward first circuit substrate 201 in fourth layer L4. First dummy line 303 formed in first layer L1 and first dummy line 303 formed in second layer L2 are arranged to be at the horizontally outer sides of first signal line 302. First dummy line 303 formed in third layer L3 and first dummy line 303 formed in fourth layer L4 are arranged to be at the horizontally outer sides of first signal line 302. In this way, first dummy line 303 travels between first circuit substrate 201 and second circuit substrate 202, and is formed as a continuous dummy line from first layer L1 to fourth layer L4. The layers of FPC substrate 203 are not limited to four layers, and may employ any number of layers.

With multilayer structured FPC substrate 203, signal lines that connect different function blocks from those of circuit section 301 can be provided in each of first layer L1 to fourth layer L4. In this way, multiple signal lines and first dummy lines 303 connected with multiple function blocks are grouped as a group of wirings, thereby detecting and alarming wire-breaking.

Second dummy line 305 is formed in the same structure as FIG. 4, and its explanation will be omitted.

The explanation of the structure of mobile terminal device 100 terminates.

A method for detecting wire-breaking of FPC substrate 203 will be described below with reference to FIG. 3.

Circuit section 301 supplies a constant current from the constant current source to first dummy line 303 and second dummy line 305. Circuit section 301 monitors the voltages of first dummy line 303 and second dummy line 305, and detects a change in voltage. For example, circuit section 301 A/D converts the detected voltage value and compares the voltage value after the conversion with a threshold, thereby detecting a change in voltage. The voltage change detection is not limited to the above method, and may employ various methods. For example, when circuit section 301 has an A/D conversion function, resistor 306 and resistor 307 may be deleted, and circuit section 301 may apply a bias to first dummy line 303 and second dummy line 305 thereby to detect a change in voltage.

In a normal state in which first dummy line 303 and second dummy line 305 are not broken, the voltages of first dummy line 303 and second dummy line 305 detected by circuit section 301 are within a certain predefined range.

In this state, when first dummy line 303 is broken, the voltage of first dummy line 303 detected by circuit section 301 is out of the predefined range. Therefore, circuit section 301 detects that the voltage of first dummy line 303 is out of the predefined range, and thereby detects the wire-breaking of first dummy line 303.

Similarly, when second dummy line 305 is broken, the voltage of second dummy line 305 detected by circuit section 301 is out of the predefined range. Thus, circuit section 301 detects that the voltage of second dummy line 305 is out of the predefined range, and thereby detects the wire-breaking of second dummy line 305.

When circuit section 301 detects the wire-breaking of first dummy line 303, mobile terminal device 100 displays and alarms, on display section 120, that first signal line 302 can be broken. When circuit section 301 detects the wire-breaking of second dummy line 305, mobile terminal device 100 displays and alarms, on display section 120, that second signal line 304 can be broken. At this time, mobile terminal device 100 can display a different alarm per function block. Thereby, the user can quickly grasp a portion where wire-breaking can possibly occur.

A stress along with the open/close operation of first casing 101 and second casing 102 is more easily applied to the outside of FPC substrate 203 than to the inside thereof. Therefore, typically first dummy line 303 is more easily broken than first signal line 302. Similarly, typically second dummy line 305 is more easily broken than second signal line 304. Thus, an alarm is given when the wire-breaking of first dummy line 303 is detected or when the wire-breaking of second dummy line 305 is detected, and thus the user can previously take a countermeasure such as repair before first signal line 302 or second signal line 304 is broken.

In the present embodiment, two first dummy lines 303 and two second dummy lines 305 may be arranged. In this case, for each of first dummy lines 303 and second dummy lines 305, the outer dummy line may be for alarm display and the inner dummy line may be for power supply stop. In this case, an alarm is given when only the outer dummy line is broken, and the power supply can be stopped when the outer dummy line is broken and further the inner dummy line is broken. Thereby, an alarm and a power supply can be stopped per function block. For example, when a signal line of the function block of the camera can be broken, the power supply to the function block of the camera is stopped and the power supply to the function block of the phone can be continued. Consequently, mobile terminal device 100 cannot use the camera function but can continuously use the call function.

As described above, according to the present embodiment, wire-breaking can be detected per function blocks and the circuit structure can be simplified, thereby restricting the processing load on the wire-breaking detection processing. According to the present embodiment, the first circuit substrate and the second circuit substrate are connected via the FPC substrate, thereby further reducing more manufacture cost than use of a coaxial line. According to the present embodiment, by giving an alarm when wire-breaking of a dummy line is detected, repair is possible before a signal line is broken, thereby avoiding an abrupt disabled state due to wire-breaking of a signal line.

In the present embodiment, two signal lines are provided, but any number of signal lines may be employed depending on the number of function blocks mounted on the mobile terminal device. In the present embodiment, one signal line is associated with one dummy line for arrangement, but the present embodiment is not limited thereto, and multiple signal lines and one dummy line may be associated and arranged, and one signal line and multiple dummy lines may be associated and arranged.

### Embodiment 2

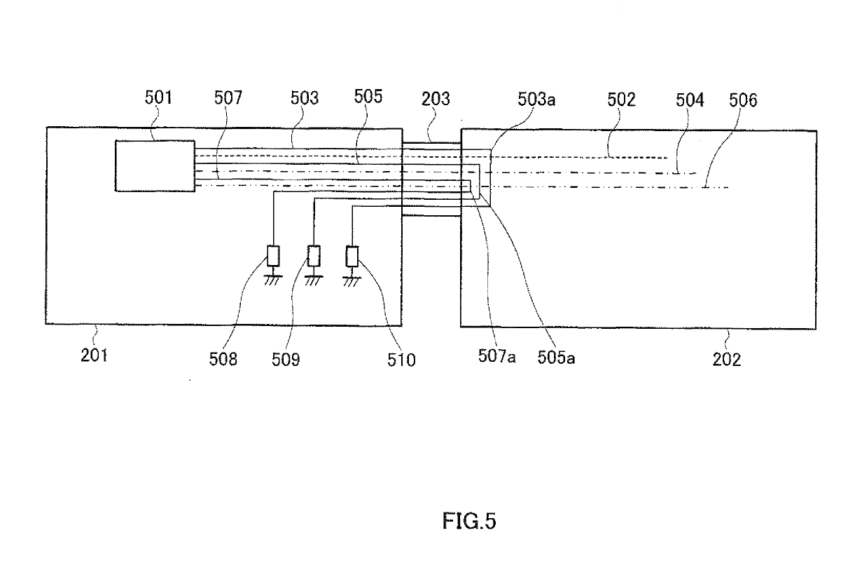

FIG. 5 is a plan view of essential sections of mobile terminal device 100 according to Embodiment 2 of the present invention.

Mobile terminal device 100 shown in FIG. 5 is such that first signal line 302, first dummy line 303, second signal line 304, second dummy line 305, resistor 306 and resistor 307 are deleted from mobile terminal device 100 according to Embodiment 1 shown in FIG. 3, first signal line 502, first dummy line 503, second signal line 504, second dummy line 505, third signal line 506, third dummy line 507, resistor 508, resistor 509 and resistor 510 are added thereto, and circuit section 501 is provided instead of circuit section 301. In FIG. 5, like reference numerals are denoted to the same constituents as those of FIG. 3, and an explanation thereof will be omitted. In the present embodiment, a perspective view of the open state of mobile terminal device 100 is the same as FIG. 1 and the plan view of the open state of mobile terminal device 100 is the same as FIG. 2, and thus an explanation thereof will be omitted. In the present embodiment, the structure of the FPC substrate is the same as FIG. 4, and thus an explanation thereof will be omitted.

First circuit substrate 201 has circuit section 501. First circuit substrate 201 prints and forms first signal line 502 and first dummy line 503 therein. First circuit substrate 201 prints and forms second signal line 504 and second dummy line 505 therein. First circuit substrate 201 prints and forms third signal line 506 and third dummy line 507 therein. First circuit substrate 201 has resistor 508, resistor 509 and resistor 510. First signal line 502, first dummy line 503, second signal line 504, second dummy line 505, third signal line 506 and third dummy line 507 may not be printed and formed, and may be formed separately from first circuit substrate 201 and may be formed in any method.

Second circuit substrate 202 prints and forms first signal line 502 and first dummy line 503 therein. Second circuit substrate 202 prints and forms second signal line 504 and second dummy line 505 therein. Second circuit substrate 202 prints and forms third signal line 506 and third dummy line 507 therein. Second circuit substrate 202 has a plurality of different function blocks (not shown). First signal line 502, first dummy line 503, second signal line 504, second dummy line 505, third signal line 506 and third dummy line 507 may not be printed and formed, and may be formed separately from second circuit substrate 202 and may be formed in any method.

FPC substrate 203 is made of a flexible material. FPC substrate 203 forms first signal line 502, first dummy line 503, second signal line 504, second dummy line 505, third signal line 506 and third dummy line 507 therein. FPC substrate 203 is provided with insulation sections that insulate first signal line 502, first dummy line 503, second signal line 504, second dummy line 505, third signal line 506 and third dummy line 507 mutually and from outside.

Circuit section 501 is electrically connected to first signal line 502, first dummy line 503, second signal line 504, second dummy line 505, third signal line 506 and third dummy line 507. Circuit section 501 supplies power to the function blocks, which are the connection destinations of first signal line 502, second signal line 504 and third signal line 506. Circuit section 501 outputs a control signal to first signal line 502, second signal line 504 and third signal line 506 for controlling the operations of the function blocks, which are the connection destinations of first signal line 502, second signal line 504 and third signal line 506. Circuit section 501 has a constant current source that supplies a constant current to first dummy line 503, second dummy line 505 and third dummy line 507. Circuit section 501 detects wire-breaking of first dummy line 503, second dummy line 505 and third dummy line 507. A wire-breaking detection method will be described later.

First signal line 502 connects circuit section 501 and the function block (not shown) provided in second casing 102. First signal line 502 is printed and formed in first circuit substrate 201, is formed in FPC substrate 203 by hinge section 103, and is printed and formed in second circuit substrate 202. First signal line 502 is formed as a continuous signal line over first circuit substrate 201, FPC substrate 203 and second circuit substrate 202.

First dummy line 503 is electrically connected at one end to circuit section 501. First dummy line 503 is extended from one end connected with circuit section 501 toward second casing 102, travels between first circuit substrate 201 and second circuit substrate 202, and is earthed at the other end to the ground section of first circuit substrate 201 via resistor 510. First dummy line 503 is provided at the horizontally outer sides of first signal line 502. The horizontally outer sides of first signal line 502 mean the upper side and the lower side of first signal line 502 in FIGS. First dummy line 503 has folding section 503a in second circuit substrate 202. First dummy line 503 is formed as a continuous dummy line over first circuit substrate 201, FPC substrate 203 and second circuit substrate 202.

Second signal line 504 connects circuit section 501 and the function block (not shown) provided in second casing 102. Second signal line 504 is printed and formed in first circuit substrate 201, is formed in FPC substrate 203 by hinge section 103, and is printed and formed in second circuit substrate 202. Second signal line 504 is formed as a continuous signal line over first circuit substrate 201, FPC substrate 203 and second circuit substrate 202.

Second dummy line 505 is electrically connected at one end to circuit section 501. Second dummy line 505 is extended from one end connected with circuit section 501 toward second casing 102, travels between first circuit substrate 201 and second circuit substrate 202, and is earthed at the other end to the ground section of first circuit substrate 201 via resistor 509. Second dummy line 505 is provided at the horizontally outer sides of second signal line 504. The horizontally outer sides of second signal line 504 mean the upper side and the lower side of second signal line 504 in FIG. 5. Second dummy line 505 has folding section 505a in second circuit substrate 202. Second dummy line 505 is formed as a continuous dummy line over first circuit substrate 201, FPC substrate 203 and second circuit substrate 202. Second dummy line 505 is arranged more inside than first dummy line 503.

Third signal line 506 connects circuit section 501 and the function block (not shown) provided in second casing 102. Third signal line 506 is printed and formed in first circuit substrate 201, is formed in FPC substrate 203 by hinge section 103, and is printed and formed in second circuit substrate 202. Third signal line 506 is formed as a continuous signal line over first circuit substrate 201, FPC substrate 203 and second circuit substrate 202.

Third dummy line 507 is electrically connected at one end to circuit section 501. Third dummy line 507 is extended from one end connected with circuit section 501 toward second casing 102, travels between first circuit substrate 201 and second circuit substrate 202, and is earthed at the other end to the ground section of first circuit substrate 201 via resistor 508. Third dummy line 507 is provided at the horizontally outer sides of third signal line 506. The horizontally outer sides of third signal line 506 mean the upper side and the lower side of third signal line 506 in FIG. 5. Third dummy line 507 has folding section 507a in second circuit substrate 202. Third dummy line 507 is formed as a continuous dummy line over first circuit substrate 201, FPC substrate 203 and second circuit substrate 202. Third dummy line 507 is arranged more inside than first dummy line 503 and second dummy line 505.

A method for detecting wire-breaking of FPC substrate 203 will be described below with reference to FIG. 5.

Circuit section 501 supplies a constant current from the constant current source to first dummy line 503, second dummy line 505 and third dummy line 507. Circuit section 501 monitors the voltages of first dummy line 503, second dummy line 505 and third dummy line 507, and detects a change in voltage. For example, circuit section 501 A/D converts the detected voltage value and compares the voltage value after the conversion with a threshold, thereby detecting a change in voltage. The voltage change detection is not limited to the above method, and may employ various methods. For example, when circuit section 501 has an A/D conversion function, resistor 508, resistor 509 and resistor 510 may be deleted, and circuit section 501 may apply a bias to first dummy line 503, second dummy line 505 and third dummy line 507 thereby to detect a change in voltage.

In a normal state where any of first dummy line 503, second dummy line 505 and third dummy line 507 is not broken, the voltages of first dummy line 503, second dummy line 505 and third dummy line 507 detected by circuit section 501 are within a certain predefined range.

In this state, when first dummy line 503 is broken, the voltage of first dummy line 503 detected by circuit section 501 is out of the predefined range. Thus, circuit section 501 detects that the voltage of first dummy line 503 is out of the predefined range, and thereby detects the wire-breaking of first dummy line 503,

Similarly, when second dummy line 505 is broken, the voltage of second dummy line 505 detected by circuit section 501 is out of the predefined range. Therefore, circuit section 501 detects that the voltage of second dummy line 505 is out of the predefined range, and thereby detects the wire-breaking of second dummy line 505.

Similarly, when third dummy line 507 is broken, the voltage of third dummy line 507 detected by circuit section 501 is out of the predefined range. Thus, circuit section 501 detects that the voltage of third dummy line 507 is out of the predefined range, and thereby detects the wire-breaking of third dummy line 507.

When circuit section 501 detects the wire-breaking of first dummy line 503 and does not detect the wire-breaking of the second dummy line, mobile terminal device 100 displays and alarms, on display section 120, that only first signal line 502 can be broken. When circuit section 501 detects the wire-breaking of second dummy line 505, mobile terminal device 100 decides that first signal line 502 is broken, and displays and alarms, on display section 120, that second signal line 504 can be broken. When circuit section 501 detects the wire-breaking of third dummy line 507, mobile terminal device 100 decides that first signal line 502 and second signal line 504 are broken, and displays and alarms, on display section 202, that third signal line 506 can be broken. At this time, mobile terminal device 100 can display a different alarm per function block. Thereby, the user can quickly grasp a portion where wire-breaking can occur.

A stress along with the open/close operation of first casing 101 and second casing 102 is more easily applied to the outside of FPC substrate 203 than to the inside thereof. Therefore, typically first dummy line 503 is more easily broken than first signal line 502. Similarly, typically second dummy line 505 is more easily broken than second signal line 504. Similarly, typically third dummy line 507 is more easily broken than third signal line 506. Thus, an alarm is given when the wire-breaking of first dummy line 503 is detected, when the wire-breaking of second dummy line 505 is detected, or when the wire-breaking of third dummy line 507 is detected, and thus the user can previously take a countermeasure such as repair before first signal line 502, second signal line 504 or third signal line 506 is broken.

In FIG. 5, the function block connected to second signal line 504 is more frequently used, that is more important than the function block connected to first signal tine 502. For example, it is assumed that the function block connected with first signal line 502 is a camera or IrDA and the function block connected with second signal line 504 is display section 120 and a control circuit that controls display section 120. Thereby, fewer failures due to wire-breaking occur in a function block with higher importance.

Similarly, in FIG. 5, the function block connected with third signal line 506 is more frequently used, that is more important than the function block connected with second signal line 504. For example, it is assumed that the function block connected with second signal line 504 is display section 202 and the control circuit that controls display section 202, and the function block connected with third signal line 506 is the control circuit that controls the call function of the phone. Thereby, fewer failures due to wire-breaking occur in a function block with higher importance.

In the present embodiment, two first dummy lines 503, two second dummy line 505 and two third dummy lines 507 may be arranged. In this case, for each of first dummy lines 503, second dummy lines 505 and third dummy lines 507, the outer dummy line may be for wire-breaking detection and the inner dummy line may be for power supply stop. For example, when the wire-breaking of second dummy line 505 is detected, the power supply to the function block connected with first signal line 502 is stopped, and an alarm is given that second signal line 504 can be broken. When the wire-breaking of third dummy line 507 is detected, the power supply to the function block connected with first signal line 502 and the function block connected with second signal line 504 is stopped, and an alarm is given that third signal line 506 can be broken.

As described above, according to the present embodiment, in addition to the effects of Embodiment 1, a signal line and a dummy line of a function block with higher importance are arranged inside the FPC substrate, thereby reducing wire-breaking of a signal line of a function block with higher importance.

In the present embodiment, a function block with higher importance is selected depending on use frequency, but the present embodiment is not limited thereto, and a function block with higher importance may be selected based on user's manual setting, or a function block with higher importance may be arbitrarily selected. In the present embodiment, two signal lines are employed, but any number of signal lines may be employed depending on the number of function blocks mounted on the mobile terminal device. In the present embodiment, one signal line and one dummy line are associated and arranged, but the present embodiment is not limited thereto, and multiple signal lines and one dummy line may be arranged in association with each other, or one signal line and multiple dummy lines may be arranged in association with each other.

### Embodiment 3

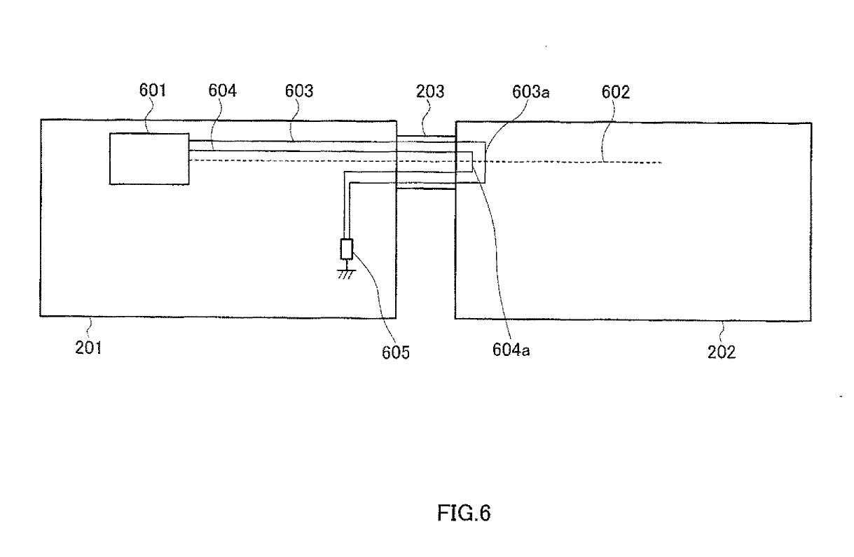

FIG. 6 is a plan view of essential sections of mobile terminal device 100 according to Embodiment 3 of the present invention.

Mobile terminal device 100 shown in FIG. 6 is such that first signal line 302, first dummy line 303, second signal line 304, second dummy line 305, resistor 306 and resistor 307 are deleted from mobile terminal device 100 according to Embodiment 1 shown in FIG. 3, and signal line 602, first dummy line 603, second dummy line 604 and resistor 605 are added thereto and circuit section 601 is provided instead of circuit section 301. In FIG. 6, like reference numerals are denoted to the same constituents as those of FIG. 3 and an explanation thereof will be omitted. In the present embodiment, a perspective view of the open state of mobile terminal device 100 is the same as FIG. 1 and the plan view of the open state of mobile terminal device 100 is the same as FIG. 2, and thus an explanation thereof will be omitted. In the present embodiment, the structure of the FPC substrate is the same as FIG. 4, and thus an explanation thereof will be omitted.

First circuit substrate 201 has circuit section 601. First circuit substrate 201 prints and forms signal line 602, first dummy line 603 and second dummy line 604 therein. First circuit substrate 201 has resistor 605. Signal line 602, first dummy line 603 and second dummy line 604 may not be printed and formed, and may be formed separately from first circuit substrate 201 and may be formed in any method.

Second circuit substrate 202 prints and forms signal line 602 therein. Second circuit substrate 202 prints and forms first dummy line 603 and second dummy line 604 therein. Second circuit substrate 202 has a function block (not shown). Signal line 602, first dummy line 603 and second dummy line 604 may not be printed and formed, and may be formed separately from second circuit substrate 202 and may be formed in any method.

FPC substrate 203 is made of a flexible material, FPC substrate 203 forms signal line 602, first dummy line 603 and second dummy line 604 therein. FPC substrate 203 is provided with insulation sections that insulate signal line 602, first dummy line 603 and second dummy line 604 mutually and from outside.

Circuit section 601 is electrically connected with signal line 602, first dummy line 603 and second dummy line 604. Circuit section 601 supplies power to the function block, which is the connection destination of signal line 602. Circuit section 601 outputs a control signal to signal line 602 for controlling the operation of the function block, which are the connection destination of signal line 602. Circuit section 601 has a constant current source that supplies a constant current to first dummy line 603 and second dummy line 604. Circuit section 601 detects wire-breaking of first dummy line 603 and second dummy line 604. A wire-breaking detection method will be described later.

Signal line 602 connects circuit section 601 with the device (not shown) provided in second casing 102. Signal line 602 is printed and formed in first circuit substrate 201, is formed in FPC substrate 203 by hinge section 103, and is printed and formed in second circuit substrate 202. Signal line 602 is formed as a continuous signal line over first circuit substrate 201, FPC substrate 203 and second circuit substrate 202.

First dummy line 603 is electrically connected at one end to circuit section 601. First dummy line 603 is extended from one end connected with circuit section 601 toward second casing 102, travels between first circuit substrate 201 and second circuit substrate 202, and is earthed at the other end on the ground section of first circuit substrate 201 via resistor 605. First dummy line 603 is provided at the horizontally outer sides of signal line 602 and second dummy line 604. The horizontally outer sides of signal line 602 mean the upper side and the lower side of signal line 602 in FIG. 6. The horizontally outer sides of second dummy line 604 mean the upper side and the lower side of second dummy line 604 in FIG. 6. First dummy line 603 has folding section 603a in second circuit substrate 202. First dummy line 603 is formed as a continuous dummy line over first circuit substrate 201, FPC substrate 203 and second circuit substrate 202.

Second dummy line 604 is electrically connected at one end to circuit section 601. Second dummy line 604 is extended from one end connected with circuit section 601 toward second casing 102, travels between first circuit substrate 201 and second circuit substrate 202, and is earthed at the other end to the ground section of first circuit substrate 201 via resistor 605. Second dummy line 604 is provided at the horizontally outer sides of signal line 602. Second dummy line 604 has folding section 604a in second circuit substrate 202. Second dummy line 604 is formed as a continuous dummy line over first circuit substrate 201, FPC substrate 203 and second circuit substrate 202.

A method for detecting wire-breaking of FPC substrate 203 will be described below with reference to FIG. 6.

Circuit section 601 supplies a constant current from the constant current source to first dummy line 603 and second dummy line 604. Circuit section 601 monitors the voltages of first dummy line 603 and second dummy line 604 and detects a change in voltage. For example, circuit section 601 A/D converts the detected voltage value and compares the voltage value after the conversion with a threshold, thereby detecting a change in voltage. The voltage change detection is not limited to the above method, and may employ various methods. For example, when circuit section 601 has an A/D conversion function, resistor 605 may be deleted and circuit section 601 may apply a bias to first dummy line 603 and second dummy line 604 thereby to detect a change in voltage.

In a normal state in which first dummy line 603 and second dummy line 604 are not broken, the voltages of first dummy line 603 and second dummy line 604 detected by circuit section 601 are within a certain predefined range.

In this state, when first dummy line 603 is broken, the voltage of first dummy line 603 detected by circuit section 601 is out of the predefined range. Thus, circuit section 601 detects that the voltage of first dummy line 603 is out of the predefined range, thereby detecting the wire-breaking of first dummy line 603.

Similarly, when second dummy line 604 is broken, the voltage of second dummy line 604 detected by circuit section 601 is out of the predefined range. Therefore, circuit section 601 detects that the voltage of second dummy line 604 is out of the predefined range, thereby detecting the wire-breaking of second dummy line 604.

When circuit section 601 detects the wire-breaking of first dummy line 603, mobile terminal device 100 displays and alarms, on display section 120, that signal line 602 can be broken. When circuit section 601 detects the wire-breaking of second dummy line 604, mobile terminal device 100 stops power supplying by circuit section 601 to signal line 602. Thereby, the power supply to the function block connected to signal line 602 can be stopped.

A stress along with the open/close operation of first casing 101 and second casing 102 is more easily applied to the outside of FPC substrate 203 than to the inside thereof. Thus, typically second dummy line 604 is more easily broken than signal line 602. Similarly, typically first dummy line 603 is more easily broken than second dummy line 604. Thus, an alarm is given when the wire-breaking of first dummy line 603 is detected, and thus a countermeasure such as repair can be taken before the power supply to the function block connected with signal line 602 stops due to the wire-breaking of second dummy line 604. The power supply by signal line 602 is stopped when the wire-breaking of second dummy line 604 is detected, thereby preventing mobile terminal device 100 from continuously being used in a failure or poor operation state.

As described above, according to the present embodiment, by giving an alarm when the wire-breaking of the dummy line is detected, repair is possible before the signal line is broken, thereby preventing an abrupt disabled state due to the wire-breaking of the signal line. According to the present embodiment, the first circuit substrate and the second circuit substrate are connected via the FPC substrate, thereby further reducing more manufacture cost than use of a coaxial line.

In the present embodiment, one signal line is provided, but any number of signal lines may be employed depending on the number of devices mounted on the mobile terminal device. In the present embodiment, one signal line is associated with two dummy lines for arrangement, but the present embodiment is not limited thereto, and multiple signal lines may be associated with two dummy lines for arrangement or one signal line may be associated with three or more dummy lines for arrangement.

The dummy lines are formed via the second circuit substrate in Embodiment 1 to Embodiment 3 described above, but the present invention is not limited thereto and the dummy lines may not necessarily routed through the second circuit substrate as long as they route through the hinge section. That is, if it is possible to detect that the signal lines can be broken in the FPC substrate due to the open/close of the casings, the dummy lines may be arbitrarily arranged. The FPC substrate is multilayer structured in Embodiment 1 to Embodiment 3 described above, but the present invention is not limited thereto and the FPC substrate may have a single-layer structure. An alarm for wire-breaking is displayed on the display section in Embodiment 1 to Embodiment 3 described above, but the present invention is not limited thereto, and an alarm for wire-breaking may be given by use of any report section such as vibration or speech. The circuit section that detects wire-breaking is provided in the first circuit substrate in Embodiment 1 to Embodiment 3 described above, but the present invention is not limited thereto and the circuit section that detects wire-breaking may be provided in the second circuit substrate.

The disclosed contents of Specification, Drawings and Abstract contained in Japanese Patent Application 2009-270035 filed on Nov. 27, 2009 are all incorporated in the present application.

### INDUSTRIAL APPLICABILITY

The substrate and mobile terminal device according to the present invention are particularly suitable for detecting wire-breaking of a signal line.

1-5. (canceled)

6. A mobile terminal device comprising: a first casing;
a second casing connected to the first casing;
a first circuit substrate provided in the first casing;
a second circuit substrate that is provided in the second casing and has a first function block having a predetermined function and a second function block having a different function from the first function block;
a connection section that is formed of a flexible print substrate in a multilayer structure, has a first signal line connecting the first circuit substrate and the first function block in the first layer of the flexible print substrate, a second signal line connecting the first circuit substrate and the second function block in the second layer adjacent to the first layer of the flexible print substrate, and dummy lines continuously extended to the first layer and the second layer of the flexible print substrate, traveling between the first circuit substrate and the second circuit substrate, and arranged at the horizontally outer sides of the first signal line and the second signal line; and
a wire-breaking detection section that is provided in the first circuit substrate or the second circuit substrate and detects wire-breaking of the dummy line.

7. The mobile terminal device according to claim 6, further comprising a report section that gives an alarm when the wire-breaking detection section detects wire-breaking.
